(19) United States
(12) Patent Application Publication
(10) Pub. No.: US 2026/0074157 A1
(43) Pub. Date: Mar. 12, 2026

(54) PLASMA PROCESSING APPARATUS AND PLASMA PROCESSING METHOD

(71) Applicant: Tokyo Electron Limited, Tokyo (JP)

(72) Inventor: Ryutaro SUDA, Miyagi (JP)

(73) Assignee: Tokyo Electron Limited, Tokyo (JP)

(21) Appl. No.: 19/392,187

(22) Filed: Nov. 18, 2025

Related U.S. Application Data
(63) Continuation of application No. PCT/JP2024/018717, filed on May 21, 2024.

(30) Foreign Application Priority Data
Jun. 1, 2023 (JP) 2023-090763

(51) Int. Cl. H01J 37/32; H01J 37/34

(52) U.S. Cl. CPC H01J 37/32467; H01J 37/32449; H01J 37/34; H01J 2237/334

(57) ABSTRACT

A plasma processing apparatus includes: a chamber; a substrate support disposed in the chamber and for supporting a substrate, the substrate support including a silicon-containing film; a gas supply for supplying a process gas including a hydrogen fluoride gas into the chamber; and a plasma generator for generating a plasma from the process gas, in which at least one of the chamber or an internal member disposed in the chamber contains phosphorus.

### CROSS-REFERENCE TO RELATED APPLICATIONS

This application is a Continuation application of PCT Application No. PCT/JP2024/018717, filed on May 21, 2024, which claims the benefit of priority from Japanese Patent Application No. 2023-090763, filed on Jun. 1, 2023. The entire contents of the above listed PCT and priority applications are incorporated herein by reference.

### BACKGROUND

### Field

The present disclosure relates to a plasma processing apparatus and a plasma processing method.

### Description of the Related Art

In the manufacturing of an electronic device, plasma etching of a silicon-containing film on a substrate is performed. In plasma etching, etching of a silicon-containing film is performed using a plasma generated from a process gas. U.S. Patent Application Publication No. 2016/0343580 discloses a process gas including a fluorocarbon gas as a process gas used in plasma etching of a silicon-containing film. Japanese Unexamined Patent Publication No. 2016-39310 discloses a process gas including a hydrocarbon gas and a hydrofluorocarbon gas as a process gas used in plasma etching of a silicon-containing film.

### SUMMARY

Disclosed herein is a plasma processing apparatus. The plasma processing apparatus includes: a chamber; a substrate support disposed in the chamber and configured to support a substrate including a silicon-containing film; a gas supply configured to supply a process gas including a hydrogen fluoride gas into the chamber; and a plasma generator configured to generate a plasma from the process gas, in which at least one of the chamber or an internal member disposed in the chamber contains phosphorus.

### BRIEF DESCRIPTION OF THE DRAWINGS

FIG. 1 is a schematic view illustrating a plasma processing apparatus according to one or more embodiments.

FIG. 2 is a schematic view illustrating the plasma processing apparatus according to one or more embodiments.

FIG. 3 is a detailed view illustrating a portion of a plasma processing apparatus according to one or more embodiments.

FIG. 4 is a detailed view illustrating a portion of another plasma processing apparatus according to one or more embodiments.

FIG. 5 is a flowchart illustrating an etching method according to one or more embodiments.

FIG. 6 is a cross-sectional view illustrating an example of a substrate to which the method in FIG. 5 can be applied.

FIG. 7 is a cross-sectional view illustrating a step of the etching method according to one or more embodiments.

FIG. 8 is a view for describing an example of a state in which a plasma processing chamber is sputtered in the step of FIG. 7.

FIG. 9 is a flowchart illustrating another etching method according to one or more embodiments.

### DETAILED DESCRIPTION

In the following description, with reference to the drawings, the same reference numbers are assigned to the same components or to similar components having the same function, and overlapping description is omitted.

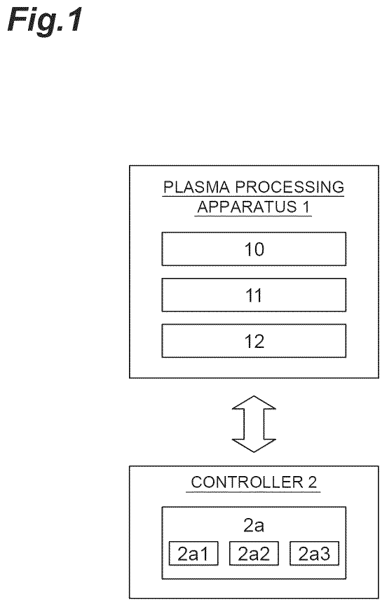

FIG. 1 is a schematic view illustrating a plasma processing apparatus according to one or more embodiments. In one or more embodiments, a plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 includes at least one gas supply port for supplying at least one process gas into the plasma processing space and at least one gas exhaust port for exhausting gases from the plasma processing space. The gas supply port is connected to a gas supply 20 to be described below and the gas exhaust port is connected to an exhaust system 40 to be described below. The substrate support 11 is disposed in the plasma processing space and has a substrate support surface for supporting the substrate.

The plasma generator 12 is configured to generate plasma from the at least one process gas supplied into the plasma processing space. The plasma formed in the plasma processing space may be a capacitively coupled plasma (CCP), an inductively coupled plasma (ICP), an electron-cyclotron-resonance (ECR) plasma, a helicon wave plasma (HWP), or a surface wave plasma (SWP), or the like. Further, various types of plasma generators including an alternating current (AC) plasma generator and a direct current (DC) plasma generator may be used. In one or more embodiments, an AC signal (AC power) used in the AC plasma generator has a frequency in the range of 100 kHz to 10 GHz. Therefore, the AC signal includes a radio frequency (RF) signal and a microwave signal. In one or more embodiments, the RF signal has a frequency in the range of 100 kHz to 150 MHz.

The controller 2 processes computer-executable instructions causing the plasma processing apparatus 1 to execute various steps described in the present disclosure. The controller 2 may be configured to control each element of the plasma processing apparatus 1 to execute various steps described herein. In one or more embodiments, the controller 2 may be partially or entirely incorporated into the plasma processing apparatus 1. The controller 2 may include a processor 2al, a storage 2a2, and a communication interface 2a3. The controller 2 is realized by, for example, a computer 2a. The processor 2al can be configured to read a program from the storage 2a2 and execute the read program to perform various control operations. This program may be stored in the storage 2a2 in advance, or may be acquired via the medium when necessary. The acquired program is stored in the storage 2a2, and is read from the storage 2a2 and executed by the processor 2al. The medium may be various storage media readable by the computer 2a, or may be a communication line connected to the communication interface 2a3. The processor 2al may be a central processing unit (CPU). The storage 2a2 may include a random-access memory (RAM), a read-only memory (ROM), a hard disk drive (HDD), a solid-state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

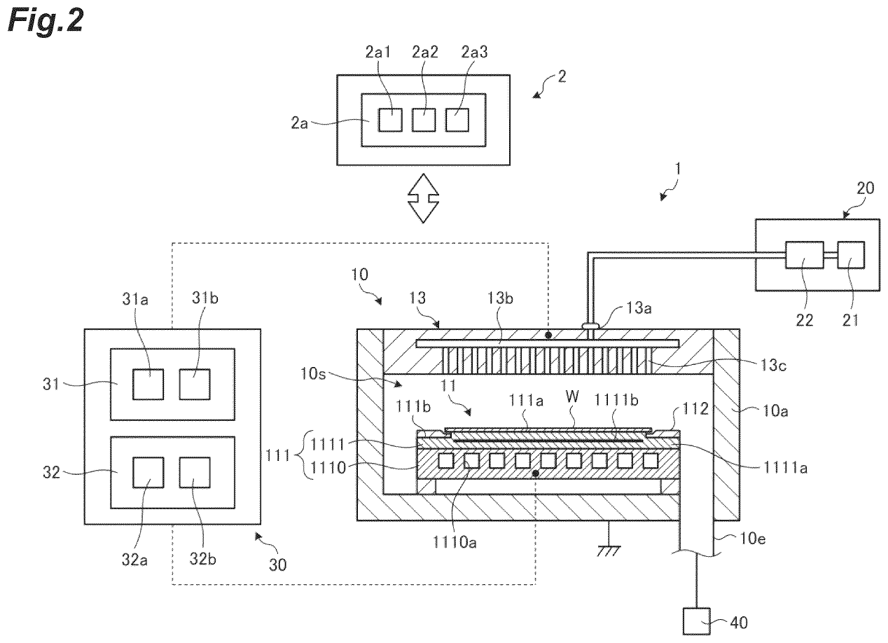

Hereinafter, a configuration example of a capacitively coupled plasma processing apparatus, which is an example of the plasma processing apparatus 1, will be described. FIG. 2 is a schematic view illustrating a plasma processing apparatus according to one or more embodiments.

The capacitively coupled plasma processing apparatus 1 includes the plasma processing chamber 10, the gas supply 20, a power supply 30, and an exhaust system 40. In addition, the plasma processing apparatus 1 includes a substrate support 11 and a gas introducer. The gas introducer is configured to introduce at least one process gas into the plasma processing chamber 10. The gas introducer includes a shower head 13. The substrate support 11 is disposed in the plasma processing chamber 10. The shower head 13 is disposed above the substrate support 11. In one or more embodiments, the shower head 13 constitutes at least a portion of the ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 to surround the substrate W on the central region 111a of the main body 111. Therefore, the central region 111a is also referred to as a substrate support surface for supporting the substrate W, while the annular region 111b is also referred to as a ring support surface for supporting the ring assembly 112.

In one or more embodiments, the main body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one or more embodiments, the ceramic member 1111a also has the annular region 111b. Further, other members surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. In addition, at least one RF/DC electrode coupled to an RF power supply 31 and/or a DC power supply 32 to be described below may be disposed in the ceramic member 1111a. In this case, at least one RF/DC electrode functions as the lower electrode. In a case where a bias RF signal and/or a DC signal to be described below is supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Therefore, the substrate support 11 includes at least one lower electrode.

The ring assembly 112 includes one or more annular members. In one or more embodiments, the one or more annular members include one or more edge rings and at least one cover ring. The edge ring is formed of a conductive material or an insulating material, and the cover ring is formed of an insulating material.

Further, the substrate support 11 may include a temperature adjusting module configured to adjust at least one of the electrostatic chuck 1111, the ring assembly 112, and the substrate to a target temperature. The temperature adjusting module may include a heater, a heat transfer medium, a flow path 1110a, or a combination thereof. A heat transfer fluid, such as brine or gas, flows into the flow path 1110a. In one or more embodiments, the flow path 1110a is formed in the base 1110, and one or more heaters are disposed in the ceramic member 1111a of the electrostatic chuck 1111. In addition, the substrate support 11 may further include a heat transfer gas supply configured to supply a heat transfer gas to a gap between a back surface of the substrate W and the central region 111a.

The shower head 13 is configured to introduce at least one process gas from the gas supply 20 into the plasma processing space 10s. The shower head 13 includes at least one gas supply port 13a, at least one gas diffusion chamber 13b, and a plurality of gas introduction ports 13c. The process gas supplied to the gas supply port 13a passes through the gas diffusion chamber 13b and is introduced into the plasma processing space 10s from the plurality of gas introduction ports 13c. Further, the shower head 13 includes at least one upper electrode. The gas introducer may include one or more side gas injectors (SGI) attached to one or more openings formed in the side wall 10a, in addition to the shower head 13.

The gas supply 20 may include at least one gas source 21 and at least one flow rate control device 22. In one or more embodiments, the gas supply 20 is configured to supply at least one process gas from a respective corresponding gas source 21 through a respective corresponding flow rate control device 22 to the shower head 13. Each flow rate control device 22 may include, for example, a mass flow controller or a pressure-controlled flow rate control device. In addition, the gas supply 20 may include at least one flow rate modulation device modulating or pulsing the flow rate of the at least one process gas.

The power supply 30 includes an RF power supply 31 coupled to the plasma processing chamber 10 via at least one impedance matching circuit. The RF power supply 31 is configured to supply at least one RF signal (RF power) to at least one lower electrode and/or at least one upper electrode. Accordingly, plasma is formed from at least one process gas supplied to the plasma processing space 10s. Therefore, the RF power supply 31 can function as at least a portion of the plasma generator 12. Further, by supplying the bias RF signal to at least one lower electrode, a bias potential is generated on the substrate W, and ion components in the formed plasma can be drawn into the substrate W.

In one or more embodiments, the RF power supply 31 includes a first RF generator 31a and a second RF generator 31b. The first RF generator 31a is configured to be coupled to at least one lower electrode and/or at least one upper electrode via at least one impedance matching circuit, and to generate a source RF signal (source RF power) for plasma generation. In one or more embodiments, the source RF signal has a frequency in the range of 10 MHz to 150 MHz. In one or more embodiments, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit and to generate a bias RF signal (bias RF power). The frequency of the bias RF signal may be the same as or different from the frequency of the source RF signal. In one or more embodiments, the bias RF signal has a frequency lower than the frequency of the source RF signal. In one or more embodiments, the bias RF signal has a frequency in the range of 100 kHz to 60 MHz. In one or more embodiments, the second RF generator 31b may be configured to generate a plurality of bias RF signals having different frequencies. The generated one or more bias RF signals are supplied to at least one lower electrode. Further, in various embodiments, at least one of the source RF signal and the bias RF signal may be pulsed.

Also, the power supply 30 may include the DC power supply 32 coupled to the plasma processing chamber 10. The DC power supply 32 includes a first DC generator 32a and a second DC generator 32b. In one or more embodiments, the first DC generator 32a is configured to be connected to at least one lower electrode and to generate a first DC signal. The generated first DC signal is applied to at least one lower electrode. In one or more embodiments, the second DC generator 32b is configured to be connected to at least one upper electrode and to generate a second DC signal. The generated second DC signal is applied to at least one upper electrode.

In various embodiments, the first and second DC signals may be pulsed. In this case, a sequence of the voltage pulses is applied to at least one lower electrode and/or at least one upper electrode. The voltage pulse may have a pulse waveform of a rectangular, trapezoidal, triangular, or a combination thereof. In one or more embodiments, a waveform generator for generating the sequence of voltage pulses from the DC signal is connected between the first DC generator 32a and at least one lower electrode. Therefore, the first DC generator 32a and the waveform generator constitute a voltage pulse generator. In a case where the second DC generator 32b and the waveform generator constitute the voltage pulse generator, the voltage pulse generator is connected to at least one upper electrode. The voltage pulse may have a positive polarity or may have a negative polarity. In addition, the sequence of the voltage pulses may include one or more positive-polarity voltage pulses and one or more negative-polarity voltage pulses in one cycle. The first and second DC generators 32a and 32b may be provided in addition to the RF power supply 31, or the first DC generator 32a may be provided instead of the second RF generator 31b.

The exhaust system 40 may be connected to, for example, a gas exhaust port 10e provided in the bottom of the plasma processing chamber 10. The exhaust system 40 may include a pressure regulating valve and a vacuum pump. The pressure in the plasma processing space 10s is adjusted by the pressure regulating valve. The vacuum pump may include a turbo molecular pump, a dry pump, or a combination thereof.

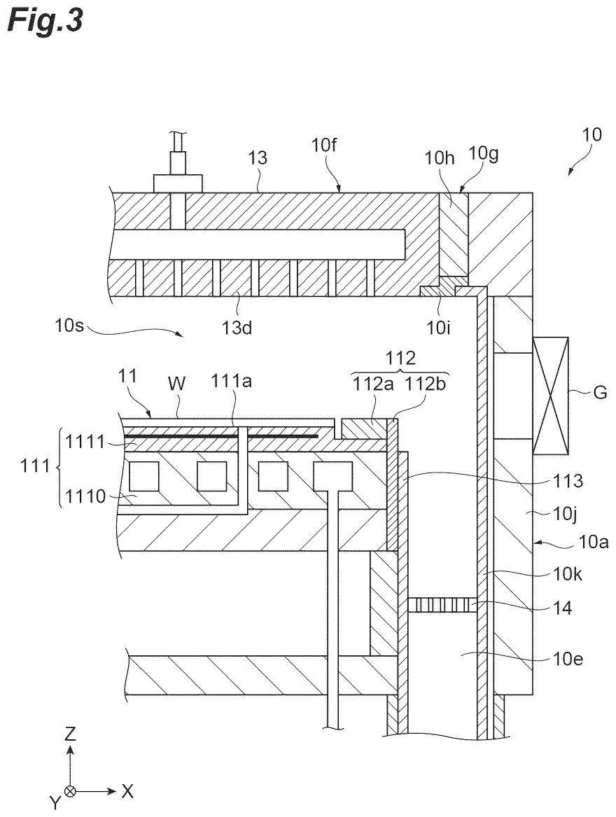

FIG. 3 is a detailed view illustrating a portion of a plasma processing apparatus according to one or more embodiments. In FIG. 3, an example of a plasma processing chamber 10 or internal members disposed in the plasma processing chamber 10 is illustrated in detail. The plasma processing chamber 10 may include a ceiling 10f disposed above the substrate support 11 and a side wall 10a connected to the ceiling 10f. The ceiling 10f may face the substrate support 11. A plasma processing space 10s is disposed between the ceiling 10f and the substrate support 11. The side wall 10a may face the substrate support 11 in a direction perpendicular to the direction in which the ceiling 10f and the substrate support 11 face each other. The plasma processing space 10s is disposed between the side wall 10a and the substrate support 11. In the following description, for convenience of description, the direction in which the ceiling 10f and the substrate support 11 face each other will be referred to as a Z-axis direction. The direction in which the side wall 10a and the substrate support 11 face each other will be referred to as an X-axis direction. The direction perpendicular to the Z-axis direction and the X-axis direction will be referred to as a Y-axis direction.

The ceiling 10f may include an upper electrode 13d included in the shower head 13 and an electrode support member 10g disposed between the upper electrode 13d and the side wall 10a. The upper electrode 13d may be disposed to face the substrate support 11 in the Z-axis direction. A surface of the upper electrode 13d may be exposed to the plasma processing space 10s. The upper electrode 13d may include at least one material selected from the group consisting of silicon and tungsten.

The electrode support member 10g may support the upper electrode 13d. The electrode support member 10g may include a shield ring 10h and a top shield ring 10i. The shield ring 10h may be disposed to surround the shower head 13 when viewed in the Z-axis direction. The shield ring 10h may have an annular shape. The top shield ring 10i may be disposed below the shield ring 10h to surround the shower head 13 when viewed in the Z-axis direction. The top shield ring 10i may be disposed continuously with the shield ring 10h in the Z-axis direction. The top shield ring 10i may have an annular shape. A surface of the top shield ring 10i may be flush with the surface of the upper electrode 13d. The surface of the top shield ring 10i may be exposed to the plasma processing space 10s. The electrode support member 10g may include quartz. The electrode support member 10g may have an insulating property. The shield ring 10h may include quartz. The shield ring 10h may have an insulating property. The top shield ring 10i may include quartz. The top shield ring 10i may have an insulating property.

The side wall 10a may include a side wall main body 10j and a deposit shield 10k. The deposit shield 10k may be provided along an inner wall surface of the side wall main body 10j. The deposit shield 10k may be exposed to the plasma processing space 10s. The deposit shield 10k may prevent by-products (deposits) generated by the plasma etching process executed in the plasma processing chamber 10 from adhering to the inner wall surface of the side wall main body 10j. The deposit shield 10k may include at least one material selected from the group consisting of yttrium oxide (Y₂O₃) and tungsten.

A gate valve G may be provided on an outer wall surface of the side wall main body 10j opposite to the inner wall surface. The gate valve G opens and closes, allowing the substrate W to be loaded into the plasma processing chamber 10.

The internal members disposed in the plasma processing chamber 10 may include the substrate support 11 and a baffle plate 14. The baffle plate 14 may be provided between the side wall 10a and the substrate support 11 in the X-axis direction. The baffle plate 14 may be provided between the plasma processing space 10s and a gas exhaust port 10e in the Z-axis direction. The baffle plate 14 may be exposed to the plasma processing space 10s. The baffle plate 14 may include at least one material selected from the group consisting of yttrium oxide (Y₂O₃) and tungsten.

The substrate support 11 may include the main body 111 having a substrate support surface (central region) 111a for supporting the substrate W, the ring assembly 112, and an outer peripheral member 113. The ring assembly 112 may be disposed to surround the substrate support surface 111a when viewed in the Z-axis direction.

The ring assembly 112 may include a focus ring 112a and a cover ring 112b. The focus ring 112a may be disposed to surround the substrate support surface 111a when viewed in the Z-axis direction. The focus ring 112a may have an annular shape when viewed in the Z-axis direction. The focus ring 112a may include at least one material selected from the group consisting of silicon and tungsten. The cover ring 112b may be disposed to surround the focus ring 112a when viewed in the Z-axis direction. The cover ring 112b may have an annular shape when viewed in the Z-axis direction. The cover ring 112b may include quartz. The cover ring 112b may have an insulating property. The focus ring 112a and the cover ring 112b may be disposed concentrically when viewed in the Z-axis direction. The focus ring 112a may be disposed inside the cover ring 112b. A surface of the focus ring 112a and a surface of the cover ring 112b may be exposed to the plasma processing space 10s.

The outer peripheral member 113 may be disposed to surround the main body 111 when viewed in the Z-axis direction. The outer peripheral member 113 may be provided along the outer periphery of the main body 111 when viewed in the Z-axis direction. The outer peripheral member 113 may be exposed to the plasma processing space 10s. The outer peripheral member 113 may prevent by-products (deposits) generated by the plasma etching process executed in the plasma processing chamber 10 from adhering to the outer periphery of the main body 111. The outer peripheral member 113 may include at least one material selected from the group consisting of yttrium oxide (Y₂O₃) and tungsten.

The outer peripheral member 113, the baffle plate 14, and the deposit shield 10k may all be made of conductive members. The outer peripheral member 113, the baffle plate 14, and the deposit shield 10k may, together with the conductive member of the base 1110 and at least one RF/DC electrode, constitute a lower electrode. A surface area of the lower electrode configured in this manner is larger than a surface area of the upper electrode 13d. By increasing a surface area ratio between the lower electrode and the upper electrode, the magnitude of the bias voltage induced in the lower electrode can be changed.

At least one of the plasma processing chamber 10 or internal members disposed in the plasma processing chamber 10 contains phosphorus. Only the plasma processing chamber 10 may contain phosphorus, only the internal members may contain phosphorus, or both the plasma processing chamber 10 and the internal members may contain phosphorus. For example, at least one selected from the group consisting of the upper electrode 13d included in the ceiling 10f, the top shield ring 10i included in the ceiling 10f, the deposit shield 10k included in the side wall 10a, the ring assembly 112, the outer peripheral member 113, and the baffle plate 14 may contain phosphorus. With respect to ring assembly 112, at least one selected from the group consisting of the focus ring 112a and the cover ring 112b may contain phosphorus. The internal members other than the ring assembly 112, the outer peripheral member 113, and the baffle plate 14 may contain phosphorus. As a method for introducing phosphorus, for example, phosphorus may be introduced into the raw material when the above-described member is cast or manufactured, or phosphorus ions may be implanted into the above-described member by ion implantation.

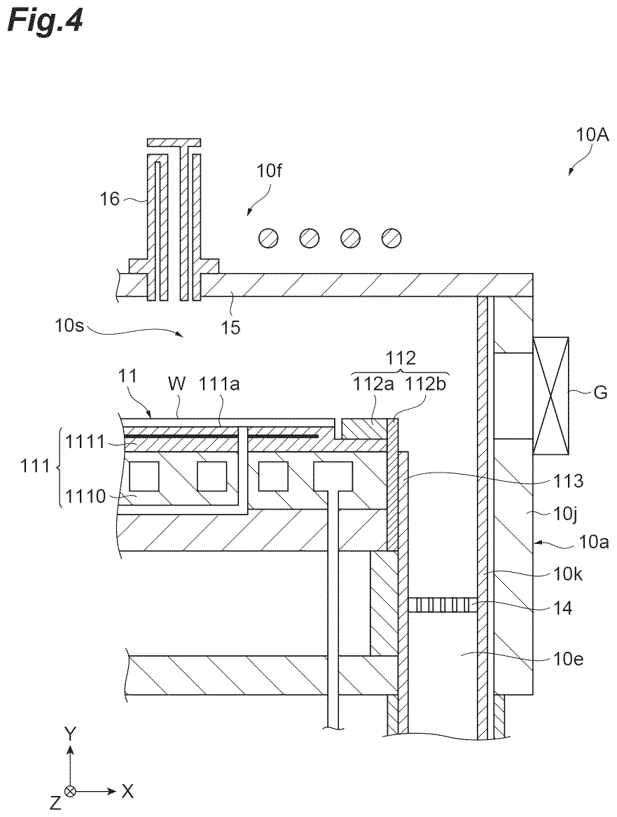

The plasma processing apparatus may be an inductively coupled plasma processing apparatus. FIG. 4 is a detailed view illustrating a portion of an inductively coupled plasma processing chamber. An inductively coupled plasma processing chamber 10A illustrated in FIG. 4 may have the same configuration as the capacitively coupled plasma processing chamber 10 described with reference to FIG. 3, except for the following points. In the inductively coupled plasma processing chamber 10A, the ceiling 10f includes a dielectric window 15 and a central gas injector 16. An inner wall surface of the dielectric window 15 may be exposed to the plasma processing space 10s. Also in the inductively coupled plasma processing apparatus, at least one of the plasma processing chamber 10A or the internal members disposed in the plasma processing chamber 10A contains phosphorus. In the inductively coupled plasma processing chamber 10A, instead of the upper electrode 13d and the top shield ring 10i, the dielectric window 15 may contain phosphorus.

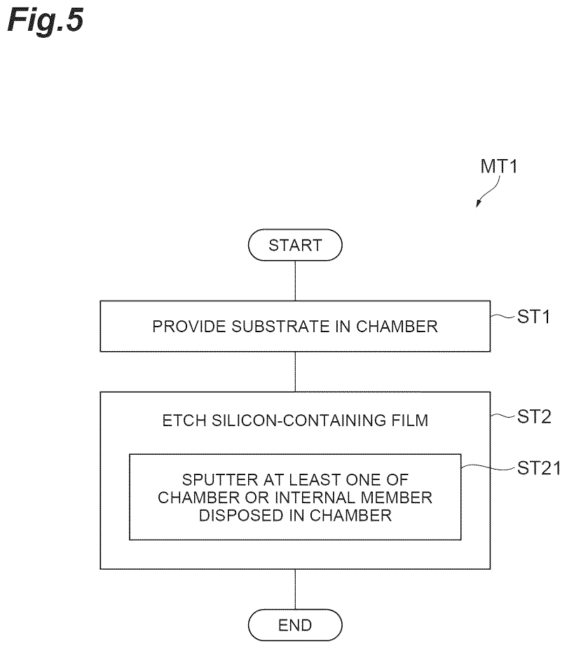

FIG. 5 is a flowchart illustrating an etching method according to one or more embodiments. An etching method MT1 illustrated in FIG. 5 (hereinafter, referred to as a “method MT1”) may be executed by the plasma processing apparatus 1 of the above-described one or more embodiments. The method MT1 may be applied to the substrate W.

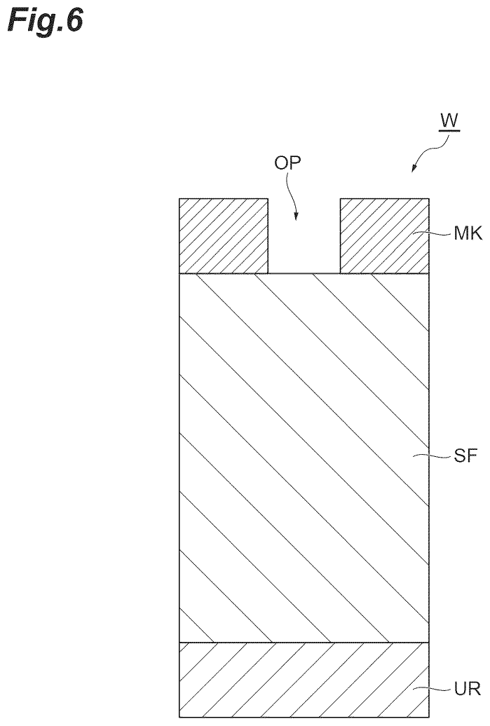

FIG. 6 is a cross-sectional view of an example of the substrate W to which the method MT1 can be applied. The substrate W illustrated in FIG. 6 is used in the manufacture of devices such as a DRAM and a 3D-NAND. The substrate W includes a silicon-containing film SF. The substrate W may further include an underlying film UR. The silicon-containing film SF may be provided on the underlying film UR. The underlying film UR may contain a material different from the material contained in the silicon-containing film SF. The underlying film UR may contain silicon.

The silicon-containing film SF may include at least one selected from the group consisting of a silicon oxide film (SiOₓ film), a silicon nitride film (SiNₓ film), and a polysilicon film (Poly-Si film). The silicon-containing film SF may include a stacked film including at least one selected from the group consisting of a silicon oxide film, a silicon nitride film, and a polysilicon film. A silicon oxide film or a silicon nitride film may be provided on the underlying film UR as an insulating film, and a polysilicon film may be provided on the insulating film.

The substrate W may further include a mask MK having an opening OP. The opening OP may have a hole pattern or a line pattern. The mask MK may be provided on the silicon-containing film SF. The mask MK may include at least one selected from the group consisting of a carbon-containing film and a metal-containing film. The carbon-containing film may include an amorphous carbon film. The metal-containing film may contain at least one metal selected from the group consisting of tungsten (W), titanium (Ti), and ruthenium (Ru). The metal-containing film may contain at least one selected from the group consisting of nitrogen, silicon, and carbon. The metal-containing film may be a tungsten-containing film. The metal-containing film may be a tungsten-containing film containing silicon or carbon. The metal-containing film may be a tungsten-containing film containing nitrogen and silicon or carbon. The metal-containing film may contain at least one selected from the group consisting of tungsten silicide (WSi), tungsten carbide (WC), tungsten silicon nitride (WSiN), tungsten carbon nitride (WCN), and tungsten nitride (WN). The metal-containing film may contain titanium nitride (TiN).

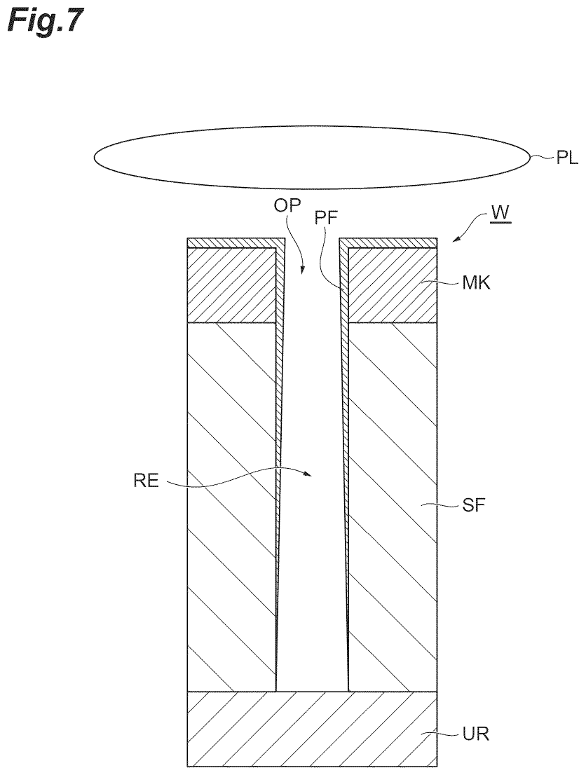

Hereinafter, the method MT1 will be described with reference to FIGS. 6 and 7 by using, as an example, the case where the method MT1 is applied to the substrate W by using the plasma processing apparatus 1 in the above-described embodiment. In the method MT1, the plasma processing chamber 10 may be used or the plasma processing chamber 10A may be used. FIGS. 6 and 7 are cross-sectional views illustrating steps of an etching method according to one or more embodiments. The controller 2 controls each part of the plasma processing apparatus 1, whereby the method MT1 can be executed in the plasma processing apparatus 1. In the method MT1, as illustrated in FIG. 2, the substrate W on the substrate support 11 disposed in the plasma processing chamber 10 is processed.

As illustrated in FIG. 5, the method MT1 may include Step ST1 and Step ST2. Step ST1 and Step ST2 can be executed in order.

### (Step ST1)

In Step ST1, the substrate W illustrated in FIG. 6 is provided. The substrate W may be supported by the substrate support 11 in the plasma processing chamber 10. In Step ST1, the substrate W may include a mask MK provided on the silicon-containing film SF.

### (Step ST2)

In Step ST2, a plasma PL is generated from process gas, and the silicon-containing film SF is etched by the plasma PL. As illustrated in FIG. 7, a recess RE is formed in the silicon-containing film SF by etching. The recess RE corresponds to the opening OP. The process gas may include a hydrogen fluoride gas (HF gas). The plasma PL contains a hydrogen fluoride etchant (HF etchant), and etches the silicon-containing film SF with the hydrogen fluoride etchant. The hydrogen fluoride etchant may include active species of hydrogen fluoride and neutral molecules of hydrogen fluoride. The hydrogen fluoride active species may include a hydrogen fluoride ion and a hydrogen fluoride radical. In the plasma PL, an H—F bond is not easily dissociated, and therefore a hydrogen fluoride etchant having an H—F bond is generated.

The process gas may include at least one selected from the group consisting of a carbon-containing gas (C-containing gas), a phosphorus-containing gas (P-containing gas), a chlorine-containing gas (Cl-containing gas), a tungsten-containing gas (W-containing gas), a boron-containing gas (B-containing gas), and a bromine-containing gas (Br-containing gas).

The carbon-containing gas that can be included in the process gas may include at least one selected from the group consisting of a fluorocarbon gas (CₓF_{y} gas) and a hydrofluorocarbon gas (CₓH_{y}F_{z} gas). The fluorocarbon gas may be at least one selected from the group consisting of CF₄, C₂F₂, C₂F₄, C₃F₈, C₄F₆, C₄F₈, and C₅F₈. The hydrofluorocarbon gas may be at least one selected from the group consisting of CHF₃, CH₂F₂, CH₃F, C₂HF₅, C₂H₂F₄, C₂H₃F₃, C₂H₄F₂, C₃HF₇, C₃H₂F₂, C₃H₂F₆, C₃H₂F₄, C₃H₃F₅, C₄H₅F₅, C₄H₂F₆, C₅H₂F₁₀, c-C₅H₃F₇, and C₃H₂F₄.

The carbon-containing gas that can be included in the process gas may contain hydrogen and a halogen. The carbon-containing gas may contain a halogen without containing hydrogen. The carbon-containing gas may be represented by a CₓH_{y}A_{z} gas (A represents a halogen). In this case, x is 1 or more, y is 0 or more and 2x+2 or less, and z may be 1 or more. The carbon-containing gas may contain at least one halogen. The carbon-containing gas may be at least one selected from the group consisting of a chloroform gas (CHCl₃ gas), a dichloromethane gas (CH₂Cl₂ gas), a CF₂Br₂ gas, a carbon tetrachloride gas (CCl₄ gas), a C₂F₅Br gas, a trifluoromethane iodide gas (CF₃I) gas, a pentafluoroiodoethane gas (C₂F₅I gas), and a C₃F₇I gas.

The phosphorus-containing gas that can be included in the process gas may include at least one selected from the group consisting of a phosphorus trifluoride gas (PF₃ gas), a phosphorus pentafluoride gas (PF₅ gas), a phosphorus trichloride gas (PCl₃ gas), a phosphorus pentachloride gas (PCl₅ gas), a phosphorus tribromide gas (PBr₃ gas), a phosphorus pentabromide gas (PBr₅ gas), and a phosphorus iodide gas (PI₃ gas).

The chlorine-containing gas that can be included in the process gas may include at least one selected from the group consisting of a chlorine gas and a hydrogen chloride gas (HCl gas).

The tungsten-containing gas that can be included in the process gas may include a tungsten hexafluoride gas (WF₆).

The boron-containing gas that can be included in the process gas may include a boron trichloride gas (BCl₃ gas).

The bromine-containing gas that can be included in the process gas may include a hydrogen bromide gas (HBr gas).

The process gas may include an inert gas. The inert gas may be an argon gas (Ar gas).

Among the flow rates of all the gases included in the process gas, the flow rate of the hydrogen fluoride gas may be highest. A ratio of the flow rate of the hydrogen fluoride gas to the total flow rate of the process gas may be 0.5 or more, 0.75 or more, or 0.9 or more.

The plasma PL may be generated from a process gas not including hydrogen fluoride gas, and the plasma PL may contain a hydrogen fluoride etchant. The silicon-containing film SF may be etched by a hydrogen fluoride etchant contained in the plasma PL. For example, the process gas may include a carbon-containing gas, including a fluorocarbon gas and hydrogen. The plasma PL generated from such a process gas contains a hydrogen fluoride etchant.

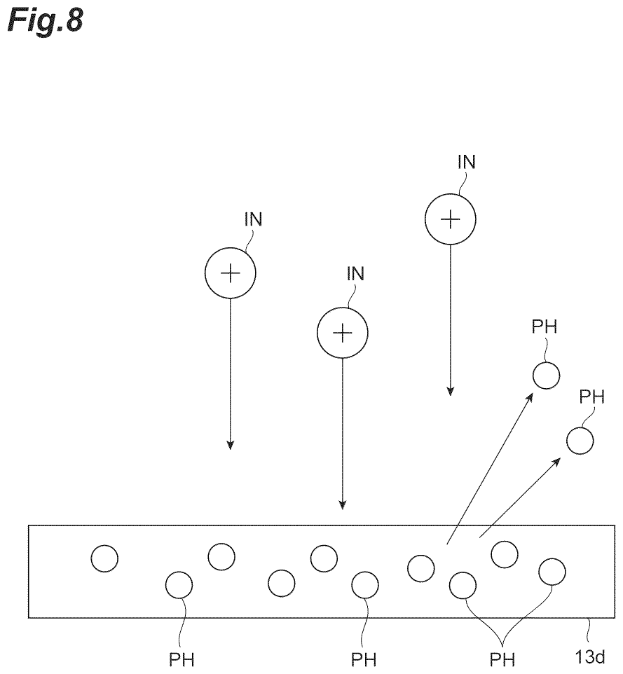

As illustrated in FIG. 5, Step ST2 may include Step ST21. In Step ST21, at least one of the plasma processing chamber 10 or the internal members disposed in the plasma processing chamber 10 may be sputtered by ions in the plasma PL. In Step ST2, etching and sputtering may be performed at the same time. FIG. 8 is a view for describing an example of a state in which the plasma processing chamber 10 or an internal member disposed in the plasma processing chamber 10 is sputtered. FIG. 8 illustrates, as an example, a state in which the upper electrode 13d containing phosphorus atoms PH is sputtered. The ion IN used for sputtering may be a hydrogen ion (H⁺ ion) generated from a hydrogen fluoride gas or a hydrogen fluoride ion (H₂F⁺). Alternatively, the ion used for sputtering may be an argon ion (Ar⁺ ion) generated from an argon gas. When the ion IN collide with the surface of the upper electrode 13d serving as a target, the phosphorus atoms PH can be released from the surface of the upper electrode 13d into the plasma PL. In the plasma PL, the phosphorus atom PH can exist as phosphorus species.

In Step ST2, phosphorus can be released into the plasma PL by, for example, sputtering, and thus phosphorus can be adhered to the surface of the silicon-containing film SF. As illustrated in FIG. 7, a protective film PF may be formed on a side wall surface of the recess RE formed in the silicon-containing film SF. The protective film PF may contain phosphorus. When the silicon-containing film SF includes a silicon oxide film, the protective film PF may include the bond of phosphorus and oxygen.

In the plasma processing apparatus 1 described above, the silicon-containing film SF is etched by the plasma PL generated from the process gas including a hydrogen fluoride gas. Since at least one of the plasma processing chamber 10 or the internal members disposed in the plasma processing chamber 10 contains phosphorus, phosphorus may be released into the plasma PL during etching. Then, phosphorus is adhered to the surface of the silicon-containing film SF. Phosphorus promotes the adsorption of an etchant (for example, a hydrogen fluoride etchant) contained in the plasma PL. By the adhesion of phosphorus to the surface of the silicon-containing film SF, the adsorption of the etchant to the silicon-containing film SF is promoted. When the amount of etchant adsorbed to the silicon-containing film SF is increased, an etching rate of the silicon-containing film SF improves up to a threshold adsorption amount, and when the threshold adsorption amount is exceeded, the etching rate decreases. The amount of etchant adsorbed to the silicon-containing film SF can be adjusted by, for example, the phosphorus concentration in the member containing phosphorus, the etchant concentration in the plasma PL, and the duration of Step ST2 (etchant supply time). Accordingly, by adjusting the amount of etchant adsorbed to the silicon-containing film SF, the etching rate of the silicon-containing film SF can be controlled.

At least one selected from the group consisting of the upper electrode 13d included in the ceiling 10f, the top shield ring 10i included in the ceiling 10f, the deposit shield 10k included in the side wall 10a, the ring assembly 112, the outer peripheral member 113, and the baffle plate 14 may contain phosphorus. In this case, in Step ST2, phosphorus is released from a member containing phosphorus into the plasma PL.

Step ST2 may include Step ST21. In this case, the release of phosphorus contained in the member into the plasma PL can be promoted by sputtering.

Among the flow rates of all the gases included in the process gas, the flow rate of the hydrogen fluoride gas may be highest. In this case, the amount of hydrogen fluoride etchant contained in the plasma PL increases. Accordingly, the adsorption of the hydrogen fluoride etchant to the silicon-containing film SF is further promoted.

The process gas may include a phosphorus-containing gas. In this case, it is possible to promote adhesion of phosphorus to the surface of the silicon-containing film SF.

Although the various exemplary embodiments have been described above, various additions, omissions, substitutions, and changes may be made without being limited to the exemplary embodiments described above. Moreover, other embodiments can be formed by combining elements in different embodiments.

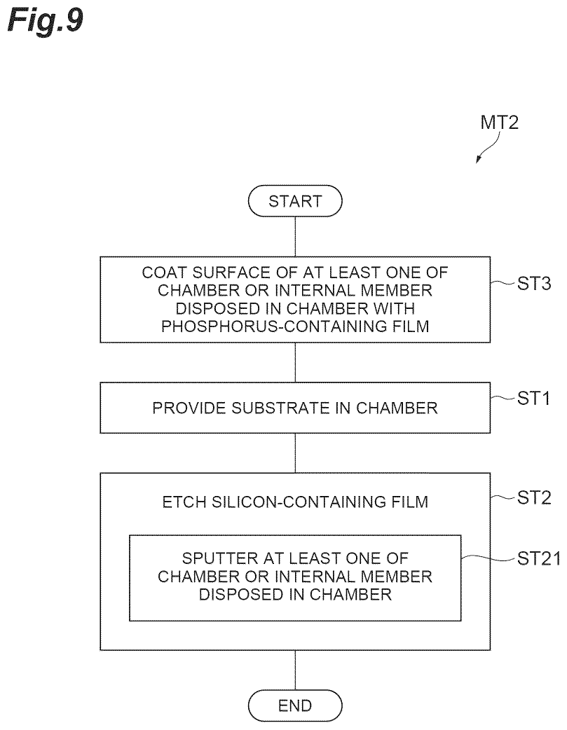

FIG. 9 is a flowchart illustrating an etching method according to a modification example (hereinafter, referred to as a “method MT2”). The method MT2 can be executed in the plasma processing apparatus 1 by controlling each part of the plasma processing apparatus 1 by the controller 2. The method MT2 may be applied in a case where the plasma processing chamber 10 and the internal members disposed in the plasma processing chamber 10 do not contain phosphorus. Differences between the method MT2 and the method MT1 will be described.

The method MT2 may include, before Step ST1, Step ST3 of generating a second plasma from a second process gas using the plasma generator 12 and coating the surface of at least one of the plasma processing chamber 10 or the internal members disposed in the plasma processing chamber 10 with a phosphorus-containing film. The second process gas includes a phosphorus-containing gas. The phosphorus-containing gas that can be included in the second process gas may include at least one selected from the group consisting of a phosphorus trifluoride gas (PF₃ gas), a phosphorus pentafluoride gas (PF₅ gas), a phosphorus trichloride gas (PCl₃ gas), a phosphorus pentachloride gas (PCl₅ gas), a phosphorus tribromide gas (PBr₃ gas), a phosphorus pentabromide gas (PBr₅ gas), and a phosphorus iodide gas (PI₃ gas).

In the method MT2, in Step ST21, the phosphorus-containing film applied on the surface of at least one of the plasma processing chamber 10 or the internal members may be sputtered by ions in the plasma PL. Accordingly, even in a case where the plasma processing chamber 10 and its internal members do not contain phosphorus, phosphorus can be released from the phosphorus-containing film into the plasma PL by sputtering.

Step ST3 may be performed each time the processing of one substrate W is completed (after Step ST2 and before Step ST1 each time). Alternatively, Step ST3 may be performed each time the processing of a plurality of substrates W (for example, one lot) is completed.

Step ST3 in the method MT2 may be applied to the method MT1. Specifically, even in a case where at least one of the plasma processing chamber 10 or the internal members disposed in the plasma processing chamber 10 contains phosphorus, the surface may be coated with a phosphorus-containing film.

In the methods MT1 and MT2, an internal member disposed in the plasma processing chamber 10 may include a bulk material containing phosphorus. Alternatively, in the methods MT1 and MT2, before Step ST2, a bulk material containing phosphorus may be provided in the plasma processing chamber 10. In Step ST21, the bulk material containing phosphorus may be sputtered by ions in the plasma PL. The bulk material may be supported on the inner wall surface of the side wall 10a, for example. The bulk material may be provided in both a case where at least one of the plasma processing chamber 10 or the internal members disposed in the plasma processing chamber 10 contains phosphorus, and a case where it does not contain phosphorus.

At least one of the plasma processing chamber 10 or the internal members disposed in the plasma processing chamber 10 may include an adsorption control substance controlling adsorption of the hydrogen fluoride etchant to the silicon-containing film SF. The adsorption control substance may include at least one selected from the group consisting of an adsorption promoting substance promoting adsorption and an adsorption inhibiting substance inhibiting adsorption.

The adsorption promoting substance may contain at least one selected from the group consisting of phosphorus, nitrogen, and hydrogen. The adsorption inhibiting substance may contain at least one selected from the group consisting of chlorine and bromine. The amount of hydrogen fluoride etchant adsorbed to the silicon-containing film SF can be increased by the adsorption promoting substance. The amount of hydrogen fluoride etchant adsorbed to the silicon-containing film SF can be reduced by the adsorption inhibiting substance. When the amount of hydrogen fluoride etchant adsorbed to the silicon-containing film SF is increased, an etching rate of the silicon-containing film SF improves up to a threshold adsorption amount, and when the threshold adsorption amount is exceeded, the etching rate decreases. The amount of hydrogen fluoride etchant adsorbed to the silicon-containing film SF can be adjusted, for example, by the concentration of the adsorption control substance in the member containing the adsorption control substance, the concentration of the hydrogen fluoride etchant in the plasma PL, and the duration of Step ST2 (duration of the hydrogen fluoride etchant). Accordingly, by adjusting the amount of hydrogen fluoride etchant adsorbed to the silicon-containing film SF, the etching rate of the silicon-containing film SF can be controlled. Therefore, the etching rate can be controlled by including an adsorption control substance in at least one of the plasma processing chamber 10 or the internal members disposed in the plasma processing chamber 10.

The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure. Here, various exemplary embodiments included in the present disclosure are described in [E1] to [E20] below.

### [E1]

A plasma processing apparatus including:
a chamber;
a substrate support disposed in the chamber and configured to support a substrate including a silicon-containing film;
a gas supply configured to supply a process gas including a hydrogen fluoride gas into the chamber; and
a plasma generator configured to generate a plasma from the process gas,
in which at least one of the chamber or an internal member disposed in the chamber contains phosphorus.

### [E2]

The plasma processing apparatus according to [E1],
in which the chamber has
   a ceiling disposed above the substrate support, and
   a side wall connected to the ceiling,
the internal member includes the substrate support and a baffle plate, the baffle plate being provided between the side wall and the substrate support,
the substrate support has
   a main body having a substrate support surface for supporting the substrate,
   a ring assembly disposed to surround the substrate support surface, and
   an outer peripheral member disposed to surround the main body, and
at least one selected from the group consisting of the ceiling, the side wall, the ring assembly, the outer peripheral member, and the baffle plate contains phosphorus.

### [E3]

The plasma processing apparatus according to [E2],
in which the ceiling includes
   an upper electrode disposed to face the substrate support, and
   an electrode support member disposed between the upper electrode and the side wall and supporting the upper electrode.

### [E4]

The plasma processing apparatus according to any one of [E1] to [E3], further including a circuitry configured to execute a process including
(a) providing the substrate on the substrate support, the substrate having a mask provided on the silicon-containing film, and
(b) generating the plasma from the process gas using the plasma generator to etch the silicon-containing film.

### [E5]

The plasma processing apparatus according to [E4],
in which (b) includes sputtering at least one of the chamber or the internal member with ions in the plasma.

### [E6]

The plasma processing apparatus according to any one of [E1] to [E5],
in which, among flow rates of all gases included in the process gas, a flow rate of the hydrogen fluoride gas is highest.

### [E7]

The plasma processing apparatus according to any one of [E1] to [E6],
in which the process gas includes at least one selected from the group consisting of a carbon-containing gas, a phosphorus-containing gas, a chlorine-containing gas, a tungsten-containing gas, a boron-containing gas, and a bromine-containing gas.

### [E8]

The plasma processing apparatus according to [E7],
in which the process gas includes the phosphorus-containing gas, and
the phosphorus-containing gas includes at least one selected from the group consisting of a phosphorus trifluoride gas, a phosphorus pentafluoride gas, a phosphorus trichloride gas, a phosphorus pentachloride gas, a phosphorus tribromide gas, a phosphorus pentabromide gas, and a phosphorus iodide gas.

### [E9]

The plasma processing apparatus according to [E7],
in which the process gas includes the carbon-containing gas, and
the carbon-containing gas includes at least one selected from the group consisting of a fluorocarbon gas and a hydrofluorocarbon gas.

### [E10]

The plasma processing apparatus according to [E7],
in which the process gas includes the carbon-containing gas, and
the carbon-containing gas contains hydrogen and a halogen.

### [E11]

The plasma processing apparatus according to any one of [E1] to [E10],
in which the silicon-containing film includes at least one selected from the group consisting of a silicon oxide film, a silicon nitride film, and a polysilicon film.

### [E12]

The plasma processing apparatus according to [E4],
in which the mask includes at least one selected from the group consisting of a carbon-containing film and a metal-containing film.

### [E13]

A plasma processing apparatus including:
a chamber;
a substrate support disposed in the chamber and configured to support a substrate including a silicon-containing film;
a gas supply configured to supply a first process gas including a hydrogen fluoride gas into the chamber;
a plasma generator configured to generate a first plasma from the first process gas; and
a circuitry configured to supply a second process gas including a phosphorus-containing gas into the chamber,
the plasma generator is configured to generate a second plasma from the second process gas, and
the circuitry is configured to execute a process including
   (a) providing the substrate on the substrate support, the substrate having a mask provided on the silicon-containing film,
   (b) generating the first plasma from the first process gas using the plasma generator to etch the silicon-containing film, and
   (c) before (b), generating the second plasma from the second process gas using the plasma generator to coat a surface of at least one of the chamber or an internal member disposed in the chamber with a phosphorus-containing film.

### [E14]

The plasma processing apparatus according to E13,
wherein the chamber includes:
   a ceiling disposed above the substrate support; and
   a side wall connected to the ceiling;
the internal member includes the substrate support and a baffle plate, the baffle plate being provided between the side wall and the substrate support,
the substrate support includes:
   a main body having a substrate support surface for supporting the substrate;
   a ring assembly surrounding the substrate support surface; and
   an outer peripheral member surrounding the main body, and
at least one selected from the group consisting of the ceiling, the side wall, the ring assembly, the outer peripheral member, and the baffle plate contains phosphorus.

### [E15]

A plasma processing apparatus including:
a chamber;
a substrate support disposed in the chamber and configured to support a substrate including a silicon-containing film;
a gas supply configured to supply a process gas into the chamber;
a plasma generator configured to generate a plasma from the process gas; and
a circuitry configured to execute a process including
   (a) providing the substrate on the substrate support, the substrate having a mask provided on the silicon-containing film, and
   (b) generating the plasma from the process gas using the plasma generator to etch the silicon-containing film with a hydrogen fluoride etchant contained in the plasma, and
at least one of the chamber or an internal member disposed in the chamber includes an adsorption control substance controlling adsorption of the hydrogen fluoride etchant to the silicon-containing film.

### [E16]

The plasma processing apparatus according to [E15],
in which the adsorption control substance includes at least one selected from the group consisting of an adsorption promoting substance promoting the adsorption and an adsorption inhibiting substance inhibiting the adsorption.

### [E17]

The plasma processing apparatus according to [E16],
in which the adsorption promoting substance contains at least one selected from the group consisting of phosphorus, nitrogen, and hydrogen.

### [E18]

The plasma processing apparatus according to [E16],
in which the adsorption inhibiting substance contains at least one selected from the group consisting of chlorine and bromine.

### [E19]

A plasma processing method including:
(a) providing a substrate in a chamber, the substrate having a silicon-containing film and a mask provided on the silicon-containing film; and
(b) generating a plasma from a process gas containing hydrogen fluoride to etch the silicon-containing film,
in which in (a) and (b), at least one of the chamber or an internal member disposed in the chamber contains phosphorus.

### [E20]

The plasma processing method according to claim 19,
wherein the chamber includes:
   a ceiling disposed above the substrate support; and
   a side wall connected to the ceiling;
the internal member includes the substrate support and a baffle plate, the baffle plate being provided between the side wall and the substrate support,
the substrate support includes:
   a main body having a substrate support surface for supporting the substrate;
   a ring assembly surrounding the substrate support surface; and
   an outer peripheral member surrounding the main body, and
at least one selected from the group consisting of the ceiling, the side wall, the ring assembly, the outer peripheral member, and the baffle plate contains phosphorus.

It is to be understood that not all aspects, advantages and features described herein may necessarily be achieved by, or included in, any one particular example. Indeed, having described and illustrated various examples herein, it should be apparent that other examples may be modified in arrangement and detail.

What is claimed is:

1. A plasma processing apparatus comprising:
a chamber;
a substrate support disposed in the chamber and configured to support a substrate including a silicon-containing film;
a gas supply configured to supply a process gas, including a hydrogen fluoride gas, into the chamber; and
a plasma generator configured to generate a plasma from the process gas,
wherein at least one of the chamber or an internal member disposed in the chamber contains phosphorus.

2. The plasma processing apparatus according to claim 1,
wherein the chamber includes:
a ceiling disposed above the substrate support; and
a side wall connected to the ceiling;
the internal member includes the substrate support and a baffle plate, the baffle plate being provided between the side wall and the substrate support,
the substrate support includes:
a main body having a substrate support surface for supporting the substrate;
a ring assembly surrounding the substrate support surface; and
an outer peripheral member surrounding the main body, and
at least one selected from the group consisting of the ceiling, the side wall, the ring assembly, the outer peripheral member, and the baffle plate contains phosphorus.

3. The plasma processing apparatus according to claim 2,
wherein the ceiling includes:
an upper electrode disposed to face the substrate support; and
an electrode support member disposed between the upper electrode and the side wall and supporting the upper electrode.

4. The plasma processing apparatus according to claim 1, further comprising a circuitry configured to execute a process including:
(a) providing the substrate on the substrate support, the substrate having a mask provided on the silicon-containing film, and
(b) generating the plasma from the process gas using the plasma generator to etch the silicon-containing film.

5. The plasma processing apparatus according to claim 4,
wherein (b) includes sputtering at least one of the chamber or the internal member with ions in the plasma.

6. The plasma processing apparatus according to claim 1,
wherein, among flow rates of all gases included in the process gas, a flow rate of the hydrogen fluoride gas is highest.

7. The plasma processing apparatus according to claim 1,
wherein the process gas further includes at least one selected from the group consisting of a carbon-containing gas, a phosphorus-containing gas, a chlorine-containing gas, a tungsten-containing gas, a boron-containing gas, and a bromine-containing gas.

8. The plasma processing apparatus according to claim 7,
wherein the process gas further includes the phosphorus-containing gas, and
the phosphorus-containing gas includes at least one selected from the group consisting of a phosphorus trifluoride gas, a phosphorus pentafluoride gas, a phosphorus trichloride gas, a phosphorus pentachloride gas, a phosphorus tribromide gas, a phosphorus pentabromide gas, and a phosphorus iodide gas.

9. The plasma processing apparatus according to claim 7,
wherein the process gas further includes the carbon-containing gas, and
the carbon-containing gas includes at least one selected from the group consisting of a fluorocarbon gas and a hydrofluorocarbon gas.

10. The plasma processing apparatus according to claim 7,
wherein the process gas further includes the carbon-containing gas, and
the carbon-containing gas contains hydrogen and a halogen.

11. The plasma processing apparatus according to claim 1,
wherein the silicon-containing film includes at least one selected from the group consisting of a silicon oxide film, a silicon nitride film, and a polysilicon film.

12. The plasma processing apparatus according to claim 4,
wherein the mask includes at least one selected from the group consisting of a carbon-containing film and a metal-containing film.

13. A plasma processing apparatus comprising:
a chamber;
a substrate support disposed in the chamber and configured to support a substrate including a silicon-containing film;
a gas supply configured to supply a first process gas including a hydrogen fluoride gas into the chamber;
a plasma generator configured to generate a first plasma from the first process gas; and
a circuitry configured to supply a second process gas including a phosphorus-containing gas into the chamber,
the plasma generator is configured to generate a second plasma from the second process gas, and
the circuitry is configured to execute a process including:
(a) providing the substrate on the substrate support, the substrate having a mask provided on the silicon-containing film,
(b) generating the first plasma from the first process gas using the plasma generator to etch the silicon-containing film, and
(c) before (b), generating the second plasma from the second process gas using the plasma generator to coat a surface of at least one of the chamber or an internal member disposed in the chamber with a phosphorus-containing film.

14. The plasma processing apparatus according to claim 13,
wherein the chamber includes:
a ceiling disposed above the substrate support; and
a side wall connected to the ceiling;
the internal member includes the substrate support and a baffle plate, the baffle plate being provided between the side wall and the substrate support,
the substrate support includes:
a main body having a substrate support surface for supporting the substrate;
a ring assembly surrounding the substrate support surface; and
an outer peripheral member surrounding the main body, and
at least one selected from the group consisting of the ceiling, the side wall, the ring assembly, the outer peripheral member, and the baffle plate contains phosphorus.

15. A plasma processing apparatus comprising:
a chamber;
a substrate support disposed in the chamber and configured to support a substrate including a silicon-containing film;
a gas supply configured to supply a process gas into the chamber;
a plasma generator configured to generate a plasma from the process gas; and
a circuitry configured to execute a process including
(a) providing the substrate on the substrate support, the substrate having a mask provided on the silicon-containing film, and
(b) generating the plasma from the process gas using the plasma generator to etch the silicon-containing film with a hydrogen fluoride etchant contained in the plasma, and
at least one of the chamber or an internal member disposed in the chamber includes an adsorption control substance controlling adsorption of the hydrogen fluoride etchant to the silicon-containing film.

16. The plasma processing apparatus according to claim 15,
wherein the adsorption control substance includes at least one selected from the group consisting of an adsorption promoting substance promoting the adsorption and an adsorption inhibiting substance inhibiting the adsorption.

17. The plasma processing apparatus according to claim 16,
wherein the adsorption promoting substance contains at least one selected from the group consisting of phosphorus, nitrogen, and hydrogen.

18. The plasma processing apparatus according to claim 16,
wherein the adsorption inhibiting substance contains at least one selected from the group consisting of chlorine and bromine.

19. A plasma processing method comprising:
(a) providing a substrate in a chamber, the substrate having a silicon-containing film and a mask provided on the silicon-containing film; and
(b) generating a plasma from a process gas containing hydrogen fluoride to etch the silicon-containing film,
wherein in (a) and (b), at least one of the chamber or an internal member disposed in the chamber contains phosphorus.

20. The plasma processing method according to claim 19,
wherein the chamber includes:
a ceiling disposed above a substrate support; and
a side wall connected to the ceiling;
the internal member includes the substrate support and a baffle plate, the baffle plate being provided between the side wall and the substrate support,
the substrate support includes:
a main body having a substrate support surface for supporting the substrate;
a ring assembly surrounding the substrate support surface; and
an outer peripheral member surrounding the main body, and
at least one selected from the group consisting of the ceiling, the side wall, the ring assembly, the outer peripheral member, and the baffle plate contains phosphorus.
